(19) United States
(12) Patent Application Publication
(10) Pub. No.: US 2006/0023765 A1
(43) Pub. Date: Feb. 2, 2006

(54) Semiconductor laser having two or more laser diode portions and a manufacturing method for the same

(75) Inventors: Toshiya Fukuhisa, Osaka (JP); Masaya Mannoh, Nara-shi (JP); Hidetoshi Furukawa, Osaka (JP); Kohji Makita, Akoh-shi (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/153,556

(22) Filed: Jun. 16, 2005

(30) Foreign Application Priority Data
Jul. 30, 2004 (JP) JP2004-224878

(51) Int. Cl. H01S 5/00

(52) U.S. Cl. 372/50.12; 372/50.1

(57) ABSTRACT

The semiconductor laser according to the present invention has a substrate used as a shared base, on which an infrared laser diode portion and a red laser diode portion are formed apart from each other. The top surfaces of the laminated layers of the individual laser diode portions have different height positions in the thickness direction of the substrate in relation to the reference point Bf. Neighboring members are formed on the outer edge of the laser, sandwiching therebetween where the laser diode portions are formed. The top surface positions of the neighboring members are all set to the same height which is higher than or equal to the top surface position of the higher laser diode portion of the two.

### BACKGROUND OF THE INVENTION

[1] Field of the Invention

The present invention relates to a semiconductor laser having two or more laser diode portions and a manufacturing method for such a semiconductor laser.

[2] Related Art

A 650 nm-band AlGaInP red laser is used as a pickup light source for reading/writing data from/to DVD-RAM and the like, while a 780 nm-band AlGaAs infrared (IR) laser is used as a pickup light source for reading/writing data from/to CD-R and the like. Of these, a red laser has a configuration as shown in FIG. 1, for example: an n-type cladding layer 302, an active layer 303, a p-type first cladding layer 304, a p-type second cladding layer 305, a current-blocking layer 306, a contact layer 307 and a p-type electrode 308 are formed in layers on one of the main surfaces of a substrate 301, and an n-type electrode 309 is formed on the other main surface of the substrate 301.

Here, making a semiconductor laser adopting the above structure requires three crystal growth processes in total including: a double-heterojunction structure formation; a current-blocking layer formation; and a buried layer formation. On the other hand, manufacture of a dual-wavelength semiconductor laser as shown in FIG. 2 necessitates at least four crystal growth processes. However, requiring a number of growth processes has remained a severe obstacle to reduction of manufacturing costs of leaser chips.

Correspondingly, as a technique for making a semiconductor laser diode portion in one crystal growth process, a ridge-waveguide semiconductor laser having an oscillation wavelength band of 660 nm has been developed and produced, in which a flow of current is concentrated by a dielectric film. One example of such a ridge-waveguide semiconductor laser is discussed in Yagi, T., et al. (IEEE Journal of Selected Topics in Quantum Electron, vol. 9, No. 5, pp. 1260-1264, September/October 2003”). As shown in FIG. 2, a semiconductor laser disclosed in this reference forms a ridge-type waveguide structure, and has a diode with a structure in which a flow of current is concentrated and light is confined by a dielectric film 406 made of, for example, SiO₂ or Si₃N₄. Specifically speaking, for instance, an n-type cladding layer 402, an active layer 403, a p-type first cladding layer 404, a p-type second cladding layer 405, a dielectric film 406 and a p-type electrode 407 are formed in layers on one of the main surfaces of a substrate 401, and an n-type electrode 408 is formed on the other main surface of the substrate 401, as shown in the figure.

Additionally, the semiconductor laser has adopted so-called a double-channel ridge waveguide structure, in which the p-type second cladding layer 405 is made to have the same thickness in the ridge and neighboring members of the ridge, in order to disperse stress exerted on the ridge. Employing this structure avoids deterioration of the semiconductor laser due to the stress on the ridge caused during a junction-down mounting process, in which a surface plane of the laser diode portion closer to the active layer 403 is bound to a submount.

In recent years, there is a demand for devices capable of handling both DVD-RAM and CD-R discs, and drives complete with optical-integrated units each corresponding to red and IR light, respectively, have been in widespread use. Furthermore, in response to recent demands for reductions in size and cost as well as streamlined procedures for optical system assembly, what is being put to practical use is a dual-wavelength semiconductor laser having a configuration in which two laser diode portions are integrated together on one substrate so that only the single optical-integrated unit is required.

A traditional dual-wavelength semiconductor laser has a configuration in which, for example, a 650 nm-band AlGaInP red laser diode portion and a 780 nm-band AlGaAs IR laser diode portion are monolithically integrated together on a single substrate. Herewith, an optical pickup capable of handling both DVD and CD can be formed as one optical-integrated unit (e.g. Japanese Laid-Open Patent Application Publication No. 2001-57462).

When a dual-wavelength semiconductor laser adopts the double-channel ridge waveguide structure, the structure will be one as shown in FIG. 3. As shown in the figure, the dual-wavelength semiconductor laser with the structure has a substrate 501, on which an IR laser diode portion 50a and a red laser diode portion 50b are formed. These diode portions 50a and 50b respectively have an n-type cladding layer 502/506, an active layer 503/507, a p-type first cladding layer 504/508, a p-type second cladding layer 505/509, a dielectric film 510, and a p-type electrode 511 formed in layers on one of the main surfaces of the substrate 501. An n-type electrode 512 shared by the diode portions 50a and 50b is formed on the other main surface of the substrate 501. A semiconductor laser having such a configuration exhibits an advantageous effect of reducing manufacturing costs, as with the semiconductor laser of FIG. 2 above.

However, it is sometimes the case with a dual-wavelength semiconductor laser employing the above double-channel ridge waveguide structure where the individual layers of the double-heterojunction structure need to be designed so that they have different thicknesses in the IR laser diode portion 50a and in the red laser diode portion 50b, in order to obtain desired characteristics specific to the respective laser diode portions 50a and 50b. For this reason, in this type of dual-wavelength semiconductor laser, the height of the IR laser diode portion 50a measured from the substrate 501 to the surface 50af of the p-type electrode 511 differs from the height of the red laser diode portion 50b measured from the substrate 501 to the surface 50bf of the p-type electrode 511, as shown in FIG. 3. Accordingly, when the junction-down mounting is implemented with the use of the dual-wavelength semiconductor laser having such a structure, the characteristics of the semiconductor laser may be severely affected due to the substrate 501 being bound not in parallel with the submount but on the angle and stress concentrating on a diode portion having a thicker double-heterojunction structure (in FIG. 3, the red laser diode portion 5ob).

In order to correct the problem regarding the tilt of the substrate against the submount in the junction-down mounting process, a dual-wavelength semiconductor laser may be designed by employing different components while making individual diode portions so as to have the same thickness in their double-heterojunction structures. However, this will create a lot of constraints in a process of designing the laser, which in turn poses a problem in terms of degrees of freedom in designing.

### SUMMARY OF THE INVENTION

The present invention was made in order to solve the above problems, and aims to provide a semiconductor laser which allows (i) accurate mounting in the junction-down mounting process, causing no tilt in the laser; (ii) reduction of stress concentrating on ridges of the individual laser diode portions; and (iii) reduction of manufacturing costs while degrees of freedom in designing being preserved, even when the semiconductor laser includes two or more laser diode portions formed on a single shared substrate and those laser diode portions have different heights from each other. In addition, the present invention also aims to offer a manufacturing method of such a semiconductor laser.

In order to accomplish the above objectives, the present invention has adopted the following configuration.

The semiconductor laser of the present invention comprises: a first laser diode portion positioned on top of a main surface of a substrate, emitting light of a first wavelength, and having a layered structure which includes a first-conductive-type cladding layer, an active layer, and a ridge-stripe second-conductive-type cladding layer successively stacked on the substrate main surface in the stated order; and a second laser diode portion positioned apart from the first laser diode portion on the substrate main surface, emitting light of a second wavelength, and having a layered structure which includes a first-conductive-type cladding layer, an active layer, and a ridge-stripe second-conductive-type cladding layer successively stacked on the substrate main surface in the stated order.

In the semiconductor laser of the present invention having the above configuration, the first and second laser diode portions are disposed so as to have top surfaces of the layered structures thereof positioned at different heights, in a thickness direction of the substrate, with respect to an opposite main surface of the substrate. First and second members each having a layered structure are respectively formed on an outer edge of the substrate. The first and second members are disposed (i) in a direction along the substrate main surface so as to sandwich therebetween where the first and second laser diode portions are formed, and (ii) in the thickness direction so as to have top surfaces of the corresponding layered structures both positioned at the same height which is higher than or equal to a higher of the first and second laser diode portions.

As described above, the semiconductor laser of the present invention has adopted a double-channel ridge waveguide structure. Herewith, the required number of growth processes can be reduced, and a low-cost laser can be achieved. In the semiconductor laser of the present invention, the first and second members are formed so as to sandwich therebetween where the first and second laser diode portions are formed and have the top surfaces of the corresponding layered structures both positioned at same height which is higher than or equal to the higher of the first and second laser diode portions. The first and second laser diode portions are disposed so as to have the top surfaces of the layered structures positioned at different heights. According to the above configuration, when a junction-down mounting is implemented with the use of the semiconductor laser of the present invention, the top surfaces of the first and second members come in contact with the submount. Accordingly, the semiconductor laser of the present invention prevents the substrate from being tilted during the junction-down mounting process, and avoids stress concentration on a single laser diode portion.

Furthermore, the semiconductor laser of the present invention does not require making the thickness of each layer in the double-heterojunction structure of the first laser diode portion equal to that of the second laser diode portion. This leads to preserving high degrees of freedom in the designing process of the laser.

Consequently, the semiconductor laser of the present invention has advantageous effects including: accurate mounting in the junction-down mounting process, causing no tilt in the laser; reduction of stress concentrating on ridges of the individual laser diode portions; and reduction of manufacturing costs while degrees of freedom in designing being preserved.

The semiconductor laser of the present invention having such advantageous effects may take variations in the configuration as follows.

[1-1] The semiconductor laser according to the present invention may adopt a configuration in which a third member having a layered structure is formed, on the substrate main surface, between the first and second laser diode portions; and the third member is disposed so as to have a top surface of the corresponding layered structure positioned at the same height as the first and second members in the thickness direction.

[1-2] The semiconductor laser according to the variation [1-1] above may adopt a configuration in which an isolation groove having a depth in the thickness direction is formed between the first and second laser diode portions; the third member is formed between the isolation groove and the first laser diode portion; a fourth member having a layered structure is formed, on the substrate, between the isolation groove and the second laser diode portion; and the fourth member is disposed so as to have a top surface of the corresponding layered structure positioned at the same height as the first, second, and third members in the thickness direction.

[1-3] The semiconductor laser according to the variation [1-2] above may adopt a configuration in which each of the first, second, third, and fourth members has a semiconductor layer formed on the top surface of the corresponding layered structure with a layer surface thereof exposed.

[1-4] The semiconductor laser according to the variation [1-3] above may adopt a configuration in which each of the first and second laser diode portions has a semiconductor layer formed on the top surface of the corresponding layered structure with a layer surface thereof exposed; and the semiconductor layers of the first and second laser diode portions and the semiconductor layers of the first, second, third, and fourth members are all made of same material.

[1-5] The semiconductor laser according to the present invention may adopt a configuration in which each of the first and second laser diode portions has a dielectric film and a semiconductor electrode successively stacked on the corresponding second-conductive-type cladding layer in the stated order.

[1-6] The semiconductor laser according to the present invention may adopt a configuration in which the first wavelength is in a range of 750 nm to 820 nm, inclusive, and the second wavelength is in a range of 630 nm to 690 nm, inclusive.

The semiconductor laser manufacturing method according to the present invention is characterized by having the following steps and features.

The semiconductor laser manufacturing method of the present invention comprises the steps of: (a) forming a first laser diode portion on top of part of a main surface of a substrate by successively stacking a first-conductive-type cladding layer, an active layer, and a ridge-stripe second-conductive-type cladding layer on the substrate main surface in the stated order; (b) forming a second laser diode portion on the substrate main surface, apart from the first laser diode portion, by successively stacking a first-conductive-type cladding layer, an active layer, and a ridge-stripe second-conductive-type cladding layer on the substrate main surface in the stated order; and (c) forming first and second members each having a layered structure on an outer edge of the substrate main surface so as to sandwich therebetween where the first and second laser diode portions are formed.

In the semiconductor laser manufacturing method of the present invention, the first and second laser diode portions are formed so as to have top surfaces of the stacked layers thereof positioned at different heights, in a thickness direction of the substrate, with respect to an opposite main surface of the substrate; and the first and second members are formed so as to have top surfaces of the layered structures thereof both positioned at the same height which is higher than or equal to a higher of the first and second laser diode portions.

The semiconductor laser manufacturing method according to the present invention having these features provides easy manufacturing implementation of a semiconductor laser having advantageous effects including: accurate mounting in the junction-down mounting process, causing no tilt in the laser; reduction of stress concentrating on ridges of the individual laser diode portions; and reduction of manufacturing costs while degrees of freedom in designing being preserved.

The semiconductor laser manufacturing method of the present invention may take variations as follows.

[2-1] The semiconductor laser manufacturing method according to the present invention may further comprise the step of: (d) forming a third member having a layered structure, on the substrate main surface, between the first and second laser diode portions so as to have a top surface of the corresponding layered structure positioned at the same height as the first and second members in the thickness direction.

[2-2] The semiconductor laser manufacturing method according to the variation [2-1] above may adopt a technique in which an isolation groove having a depth in the thickness direction is formed between the first and second laser diode portions; and the third member is formed between the isolation groove and the first laser diode portions. Here, the semiconductor laser manufacturing method further comprises the step of: (e) forming a fourth member having a layered structure, on the substrate main surface, between the isolation groove and the second laser diode portion so as to have a top surface of the corresponding layered structure positioned at the same height as the first, second, and third members in the thickness direction.

[2-3] The semiconductor laser manufacturing method according to the variation [2-2] above may adopt a technique in which the first, second third, and fourth members are formed so as to respectively have a semiconductor layer formed on the top surface of the corresponding layered structure with a layer surface thereof exposed.

[2-4] The semiconductor laser manufacturing method according to the variation [2-3] above may adopt a technique in which, in the steps (a) and (b), the first and second laser diode portions are formed so as to respectively have a semiconductor layer formed on top of the top surface of the corresponding stacked layers with a layer surface thereof exposed; and in the steps (c), (d), and (e), the semiconductor layers of the first, second, third, and fourth members are made of the same material as the semiconductor layers of the first and second laser diode portions.

[2-5] The semiconductor laser manufacturing method according to the present invention may adopt a technique in which, in each of the steps (a) and (b), a dielectric film and a semiconductor electrode are successively stacked on the corresponding second-conductive-type cladding layer in the stated order.

[2-6] The semiconductor laser manufacturing method according to the present invention may adopt a technique in which the steps (a) and (b) are implemented with the substeps of: (o) successively stacking the first-conductive-type cladding layer, the active layer, and the second-conductive-type cladding layer on top of the substrate main surface in the stated order; (p) selectively removing at least the second-conductive-type cladding layer and the active layer from part of the stacked layers formed in the substep (o); (q) successively stacking a first-conductive-type cladding layer, an active layer, and a second-conductive-type cladding layer, in the stated order, on top of a top surface of the stacked layers after the substep (p) has finished in a manner to be superimposed over an entire extent of the substrate main surface; (r) selectively removing one ore more of the stacked layers formed in the substep (q) from both sides of where the first laser diode portion is to be formed; (s) selectively removing at least two of the stacked layers formed in the substep (q) from where the first laser diode portion is to be formed; (t) forming a first ridge stripe by selectively removing part of the second-conductive-type cladding layer of the substep (of) from where the first laser diode portion is to be formed; and (u) forming a second ridge stripe by selectively removing part of the second-conductive-type cladding layer of the substep (q) from where the second laser diode portion is to be formed.

### BRIEF DESCRIPTION OF THE DRAWINGS

These and other objects, advantages and features of the invention will become apparent from the following description thereof taken in conjunction with the accompanying drawings which illustrate specific embodiments of the invention. In the drawings:

FIG. 1 is a structural cross section showing a ridge-waveguide laser having a buried epitaxial layer, according to a conventional technology;

FIG. 2 is a structural cross section showing a laser having a double-channel ridge waveguide structure according to a conventional technology;

FIG. 3 is a structural cross section showing a laser's configuration in which a double-channel ridge waveguide structure of the conventional technology is applied to a dual-wavelength semiconductor laser;

FIG. 4 is a structural cross section showing a dual-wavelength semiconductor laser 10 according to a first embodiment;

FIG. 5A is a cross sectional view showing one step of a manufacturing procedure of the dual-wavelength semiconductor laser 10;

FIG. 5B is a cross sectional view showing another step of the manufacturing procedure of the dual-wavelength semiconductor laser 10;

FIG. 5C is a cross sectional view showing another step of the manufacturing procedure of the dual-wavelength semiconductor laser 10;

FIG. 5D is a cross sectional view showing another step of the manufacturing procedure of the dual-wavelength semiconductor laser 10;

FIG. 6A is a cross sectional view showing another step of the manufacturing procedure of the dual-wavelength semiconductor laser 10;

FIG. 6B is a cross sectional view showing another step of the manufacturing procedure of the dual-wavelength semiconductor laser 10;

FIG. 6C is a cross sectional view showing another step of the manufacturing procedure of the dual-wavelength semiconductor laser 10;

FIG. 7A is a cross sectional view showing another step of the manufacturing procedure of the dual-wavelength semiconductor laser 10;

FIG. 7B is a cross sectional view showing another step of the manufacturing procedure of the dual-wavelength semiconductor laser 10;

FIG. 7C is a cross sectional view showing another step of the manufacturing procedure of the dual-wavelength semiconductor laser 10;

FIG. 8 is a structural cross section showing a dual-wavelength semiconductor laser 12 according to a first modification;

FIG. 9 is a structural cross section showing a dual-wavelength semiconductor laser 14 according to a second modification;

FIG. 10 is a structural cross section showing a dual-wavelength semiconductor laser 20 according to a second embodiment;

FIG. 11A is a cross sectional view showing one step of a manufacturing procedure of the dual-wavelength semiconductor laser 20;

FIG. 11B is a cross sectional view showing another step of the manufacturing procedure of the dual-wavelength semiconductor laser 20;

FIG. 11C is a cross sectional view showing another step of the manufacturing procedure of the dual-wavelength semiconductor laser 20;

FIG. 11D is a cross sectional view showing another step of the manufacturing procedure of the dual-wavelength semiconductor laser 20;

FIG. 12A is a cross sectional view showing another step of the manufacturing procedure of the dual-wavelength semiconductor laser 20;

FIG. 12B is a cross sectional view showing another step of the manufacturing procedure of the dual-wavelength semiconductor laser 20;

FIG. 12C is a cross sectional view showing another step of the manufacturing procedure of the dual-wavelength semiconductor laser 20;

FIG. 12D is a cross sectional view showing another step of the manufacturing procedure of the dual-wavelength semiconductor laser 20;

FIG. 13A is a cross sectional view showing another step of the manufacturing procedure of the dual-wavelength semiconductor laser 20;

FIG. 13B is a cross sectional view showing another step of the manufacturing procedure of the dual-wavelength semiconductor laser 20;

FIG. 13C is a cross sectional view showing another step of the manufacturing procedure of the dual-wavelength semiconductor laser 20;

FIG. 14 is a structural cross section showing a dual-wavelength semiconductor laser 22 according to a third modification; and

FIG. 15 is a structural cross section showing a dual-wavelength semiconductor laser 24 according to a fourth modification; and

### DESCRIPTION OF PREFERRED EMBODIMENTS

The best modes for implementing the present invention are described next with the aid of drawings. Note that embodiments described below are merely examples for illustrating the configurations, functions and effects of the present invention, and therefore the present invention is not confined to these.

### 1. First Embodiment

A first embodiment is described below by taking as an example a dual-wavelength semiconductor laser adopting a double-channel ridge waveguide structure and having a 780 nm-band IR laser diode portion and a 660 nm-band red laser diode portion formed together on a shared substrate.

1.1 Configuration of Laser

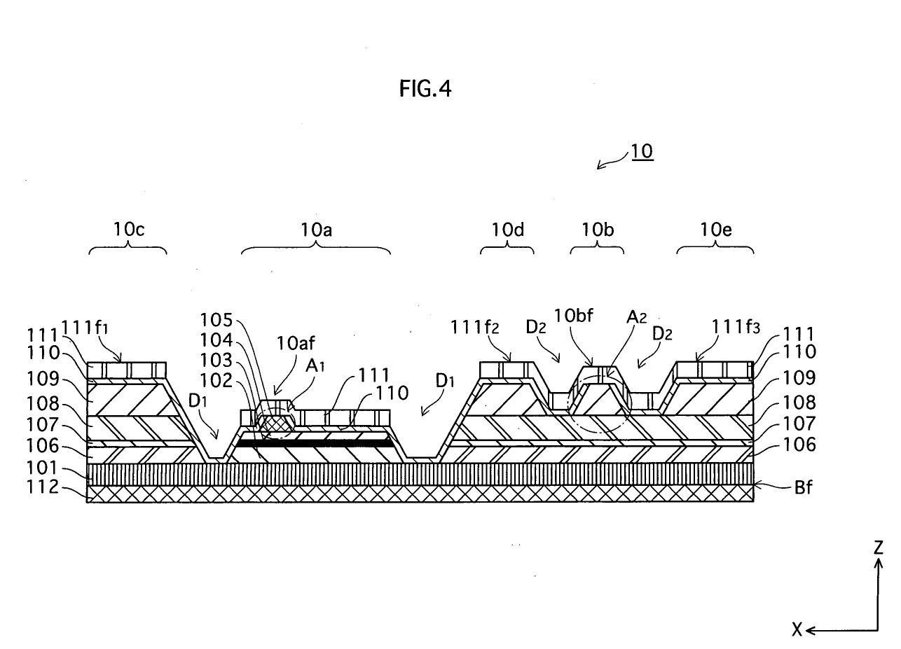

First, the configuration of a dual-wavelength semiconductor laser 10 according to the present embodiment is described with the aid of FIG. 4. FIG. 4 is a structural cross section of the dual-wavelength semiconductor laser 10. Although FIG. 4 shows a structural cross section of the dual-wavelength semiconductor laser 10, the real laser in fact has other than the components shown in FIG. 4. Two reflecting mirrors arranged in such a way as to face the cleavage plane of crystal are respectively positioned on the near and far sides of the figure, whereby an optical resonator is formed.

As shown in FIG. 4, the laser 10 has an n-type GaAs substrate 101 to be a shared base on which an IR laser diode portion 10a having an oscillation wavelength band of 780 nm and a red laser diode portion 10b having an oscillation wavelength of 660 nm are formed. The IR laser diode portion 10a and the red laser diode portion 10b are configured with a space therebetween in the x-direction in FIG. 4. Additionally, neighboring members 10c-10e are formed in the vicinity of these diode portions 10a and 11b.

The IR laser diode portion 10a is, as shown in FIG. 4, composed of an IR laser's n-type cladding layer 102, an IR laser's active layer 103, an IR laser's p-type first cladding layer 104, an IR laser's p-type second cladding layer 105, a dielectric film 110, a p-type electrode 111 which are formed in layers on one of the main surfaces of the substrate 101 (the upper main surface in the z-direction in FIG. 4), as well as an n-type electrode 112 is formed on the other main surface of the substrate 101 (the lower main surface in the z-direction in FIG. 4). Here, the entire upper main surface of the p-type first cladding layer 104 is covered by the dielectric film 110, except for where the p-type second cladding layer 105 is superimposed. On the other hand, the main surface of the p-type second cladding layer 105 superimposed over the top of the p-type first cladding layer 104 is not blanketed by the dielectric film 110, and therefore has direct contact with the p-type electrode 111. According to such a configuration, a ridge A₁ is formed.

Note that the active layer 103 in the IR laser diode portion 10a is formed by a quantum well structure with an oscillation wavelength band of 780 nm. In addition, a p-type second cladding layer 109 in the neighboring member 10c also has an additional function as an IR laser's protective layer.

On the other hand, the red laser diode portion 10b is, as shown in FIG. 4, composed of a red laser's n-type cladding layer 106, a red laser's active layer 107, a red laser's p-type first cladding layer 108, a red laser's p-type second cladding layer 109, the dielectric film 110, the p-type electrode 111 which are formed in layers on one of the main surfaces of the substrate 101 (the upper main surface in the z-direction in FIG. 4), as well as the n-type electrode 112 formed on the other main surface of the substrate 101 (the lower main surface in the z-direction in FIG. 4). Here, the main surface of the p-type second cladding layer 109 in the red laser diode portion 10b is not blanketed by the dielectric film 110, and a ridge A₂ is formed.

Note that the active layer 107 in the red laser diode portion 10b is formed by a quantum well structure with an oscillation wavelength band of 660 nm. In addition, the p-type second cladding layer 109 in the neighboring members 10d and 10e also has an additional function as a red laser's protective layer.

As shown in FIG. 4, although the neighboring members 10c-10e basically have a laminated structure composed of the same material layers as in the above red laser diode portion 10b, ridges are not formed therein and the p-type second cladding layer 109 in the neighboring members 10c-10e is covered by the dielectric film 110.

In the z-direction in FIG. 4, grooves D₁ are respectively formed on either side of the IR laser diode portion 10a between the neighboring members 10c and 10d. The layers 102-105/106-109 have been removed from these grooves D₁ so that the dielectric film 110 has contact with the substrate 101, and the p-type electrode 111 has also been removed. That is, the grooves D₁ are so-called isolation grooves used to separate diode portions.

On the other hand, grooves D₂ are respectively formed, in the z-direction in FIG. 4, on either side of the red laser diode portion 10b between the neighboring members 10d and 10e. The p-type second cladding layer 109 has been removed from the grooves D₂ so that the dielectric film 110 has contact with the p-type first cladding layer 108.

1.2 Height Relationship of Respective Portions and Regions

In the dual-wavelength semiconductor laser 10 having the above-mentioned configuration, the IR laser diode portion 10a, red laser diode portion 10b, and respective neighboring members 10c-10e have the following height relationship.

As shown in FIG. 4, in the dual-wavelength semiconductor laser 10 according to the present embodiment, the IR laser diode portion 10a is set to be the lowest among the two diode portions 10a and 10b and three neighboring members 10c-10e. The red laser diode portion 10b is set to be the second lowest of them, while the neighboring members 10c-10e all having the same height are set to be the highest. Here, the height difference between the red laser diode portion 10b and the neighboring members 10c-10d is only the thickness of the dielectric film 110, and therefore it can be considered that they all have substantially the same height.

To be more specific, here the position of the lower main surface of the substrate 101 (the main surface on which the n-type electrode 112 is laid) in the z-direction is used as a reference point Bf. The positions, in the z-direction, of the individual upper surfaces of the p-type electrode 111 in the diode portions 10a and 10b and the neighboring members 10c-10e are also used as reference points 10af, 10bf, 111f₁, 111f₂, and 111f₃, respectively. In this situation, the heights of these portions are designed to satisfy the following positional relationships in the z-direction.
(10af-Bf)<(10bf-Bf) Equation 1.
(10bf-Bf)<(111f₁-Bf)=(111f₂-Bf)=(111f₃-Bf) Equation 2.

As described above, the height difference between the point 10bf of the red laser diode portion 10b and each of the individual points 111f₁, 111f₂, and 111f₃ of the neighboring members 10c-10e is the thickness of the dielectric film 110, and the difference is almost negligible. In view of this, Equation 2 above can be deemed as:
(10bf-Bf)≈(111f₁-Bf)=(111f₂-Bf)=(111f₃-Bf) Equation 3.
1.3 Advantageous Effects of Dual-Wavelength Semiconductor Laser 10

In the dual-wavelength semiconductor laser 10 according to the first embodiment, the neighboring members 10c-10e are set higher than the IR laser diode portion 10a while being set slightly higher than the red laser diode portion 10b. The neighboring members 10c and 10e are disposed outward of the two diode portions 10a and 10b in the x-direction while the neighboring member 10d is positioned between the diode portions 10a and 10b.

The neighboring members 10c-10e are set to the same height as indicated by the above Equations 2 and 3. Thus, in the dual-wavelength semiconductor laser 10 of the present embodiment, the substrate 101 is bound in parallel with the submount without tilt during the junction-down mounting process due to this height setting. Furthermore, since the substrate 101 does not tilt against the submount in the junction-down mounting process, stress does not concentrate on the diode portion having a thicker double-heterojunction structure (the red laser diode portion 10b in FIG. 4), and thereby the characteristics of the semiconductor laser can be maintained at an effective level.

Since the substrate 101 is not tilted against the submount in the junction-down mounting process, the dual-wavelength semiconductor laser 10 of the present embodiment has an advantageous effect of being less likely to be subject to constraints on heights of the diode portions 10a and 10b in the laser designing.

In addition, since the top surface positions of the IR laser diode portion 10a and the red laser diode portion 10b are not necessarily at the same height, the dual-wavelength semiconductor laser 10 also has an advantageous effect of having fewer constraints in the designing process of the laser.

Table 1 shows examples of individual components used for the dual wavelength semiconductor laser 10.

TABLE 1

| | | Conductive | Thickness | Carrier Concentration |
|---|---|---|---|---|
| Component | Material | Type | (μm) | (cm⁻³) |
| Substrate 101 | GaAs | n type | — | 1 × 10¹⁸ |
| | (Si dope) | | | |
| IR laser n-type | (Al_{0.7}Ga_{0.3})_{0.5}In_{0.5}P | n type | 2.0 | 1 × 10¹⁸ |
| cladding layer | (Si dope) | | | |
| 102 | | | | |
| IR laser active | GaAs/Al_{0.4}Ga_{0.6}As | — | 0.08 | — |
| layer 103 | Quantum Well | | | |
| IR laser p-type | (Al_{0.7}Ga_{0.3})_{0.5}In_{0.5}P | p type | 0.2 | 5 × 10¹⁷ |
| first cladding | (Zn dope) | | | |
| layer 104 | | | | |
| IR laser p-type | (Al_{0.7}Ga_{0.3})_{0.5}In_{0.5}P | p type | 1.4 | 1 × 10¹⁸ |
| second cladding | (Zn dope) | | | |
| layer 105 | | | | |
| Red laser n-type | (Al_{0.7}Ga_{0.3})_{0.5}In_{0.5}P | n type | 2.0 | 1 × 10¹⁸ |
| cladding layer | | | | |
| 106 | (Si dope) | | | |
| Red laser active | Ga_{0.45}In_{0.55}P/ | — | 0.15 | — |
| layer 107 | (Al_{0.5}Ga_{0.5})In_{0.5}P | | | |
| | Quantum Well | | | |
| Red laser p-type | (Al_{0.7}Ga_{0.3})_{0.5}In_{0.5}P | p type | 0.4 | 3 × 10¹⁷ |
| first cladding | (Zn dope) | | | |
| layer 108 | | | | |
| Red laser p-type | (Al_{0.7}Ga_{0.3})_{0.5}In_{0.5}P | p type | 2.2 | 8 × 10¹⁷ |
| second cladding | (Zn dope) | | | |
| layer 109 | | | | |

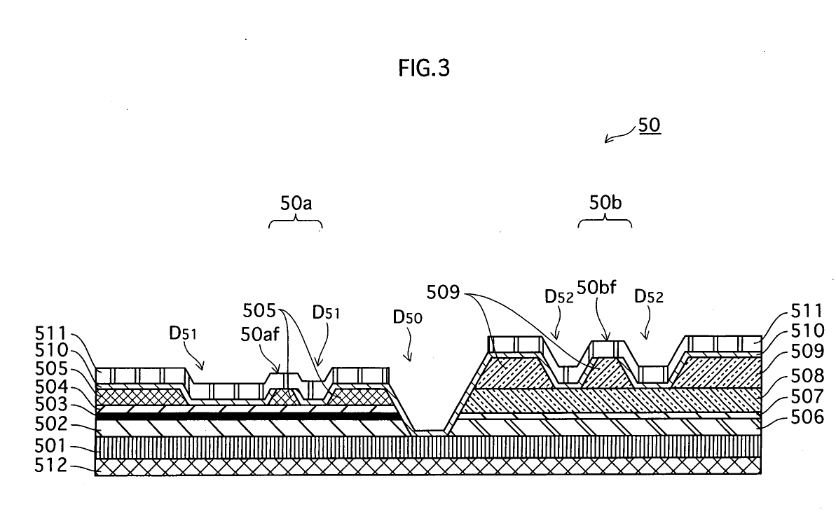

When the components shown in Table 1 are adopted, the height of the IR laser diode portion 10a (10af-Bf) is 3.68 μm, and the height of the red laser diode portion 10b (10bf-Bf) is 4.75 μm. Here, a conventional double-wavelength semiconductor laser having a double-channel ridge waveguide structure, in which no neighboring members are formed as shown in FIG. 3, about 1 μm or more difference in height will be made between the laser diode portions. Accordingly, the substrate is tilted in the junction-down mounting process, which causes adverse effects on the characteristics of the laser.

Contrarily, the dual-wavelength semiconductor laser 10 of the present embodiment is supported by the top surfaces of the neighboring members 10c-10e in the junction-down mounting process even when the height difference between the diode portions 10a and 10b is about 1 μm or more. Herewith, the tilt of the substrate 101 in the junction-down mounting process is prevented, which in turn prevents the concentration of stress on the ridges A₁ and A₂.

1.4 Manufacturing Method of Dual-Wavelength Semiconductor Laser 10

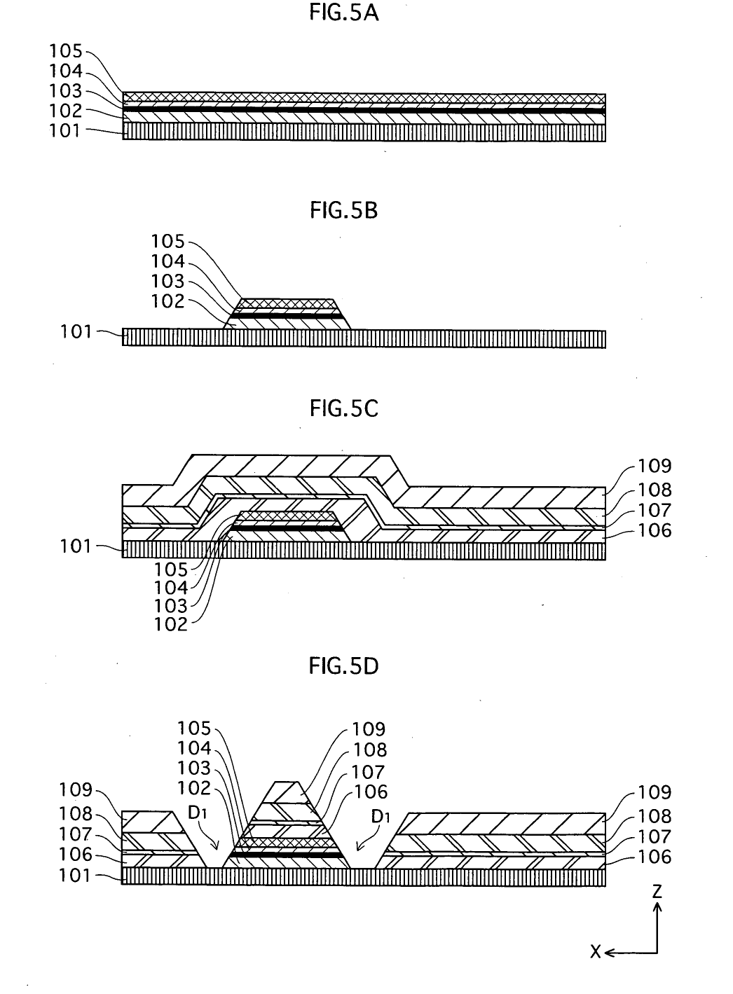

Next is described a method for manufacturing the dual-wavelength semiconductor laser 10 of the first embodiment with the aid of FIGS. 5A to 7C. FIGS. 5A to 7C are process drawings showing main steps of the manufacturing procedure of the dual-wavelength semiconductor laser 10 according to the present embodiment. Note that technologies regarding MOCVD (Metal-Organic Chemical Vapor Deposition) crystal growth, photolithography, etching of the semiconductor, dielectric film, and electrodes, CVD dielectric film deposition, and vapor deposition for electrode formation in the respective processes are all publicly well known, and therefore detailed descriptions for these technologies are omitted here.

By using the MOCVD technique, the IR laser's n-type cladding layer 102, the IR laser's active layer 103, the IR laser's p-type first cladding layer 104, and the IR laser's p-type second cladding layer 105 are formed on the n-type GaAs substrate 101 in the stated order, as shown in FIG. 5A.

Next, on either side of where the IR laser diode portion 10a is to be formed, the n-type cladding layer 102, the active layer 103, the p-type first cladding layer 104, and the p-type second cladding layer 105 are removed by photolithography and etching.

As shown in FIG. 5C, the red laser's n-type cladding layer 106, the red laser's active layer 107, the red laser's p-type first cladding layer 108, and the red laser's p-type second cladding layer 109 are formed in the stated order by the MOCVD technique.

Then, as shown in FIG. 5D, on either side adjoining where the IR laser diode portion 10a is to be formed, the n-type cladding layer 106, the active layer 107, the p-type first cladding layer 108, the p-type second cladding layer 109 are removed by photolithography and etching to form the grooves D₁.

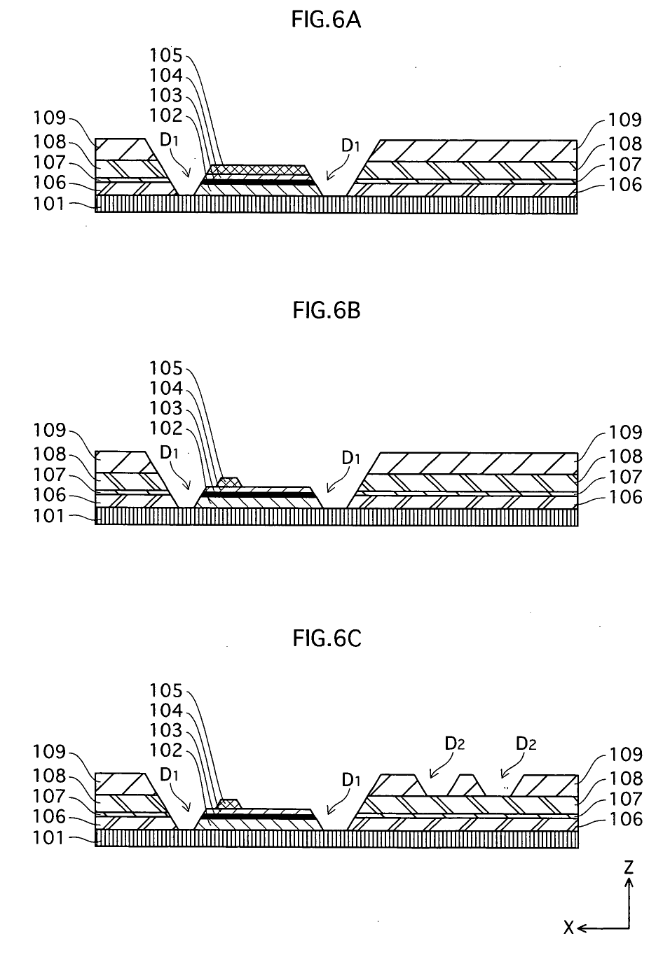

Next, the n-type cladding layer 106, the active layer 107, the p-type first cladding layer 108, and the p-type second cladding layer 109 remaining on the p-type second cladding layer 105 in the area where the IR laser diode portion 10a is to be formed are removed by photolithography and etching, as shown in FIG. 6A.

Subsequently, as shown in FIG. 6B, part of the p-type second cladding layer 105 in the area where the IR laser diode portion 10a is to be formed is removed by photolithography and etching to form a ridge.

As shown in FIG. 6C, on either side adjoining where the red laser diode portion 10b is to be formed, part of the p-type second cladding layer 109 is removed by photolithography and etching. Herewith, a ridge is formed in the area where the red laser diode portion 10b is to be formed at the same time of the formation of the grooves D₂ on both sides of the ridge. Here, the p-type second cladding layer 109 remaining in the areas adjoining where the red laser diode portion 10b is to be formed also has a function as a red laser's protective layer when the laser 10 is complete.

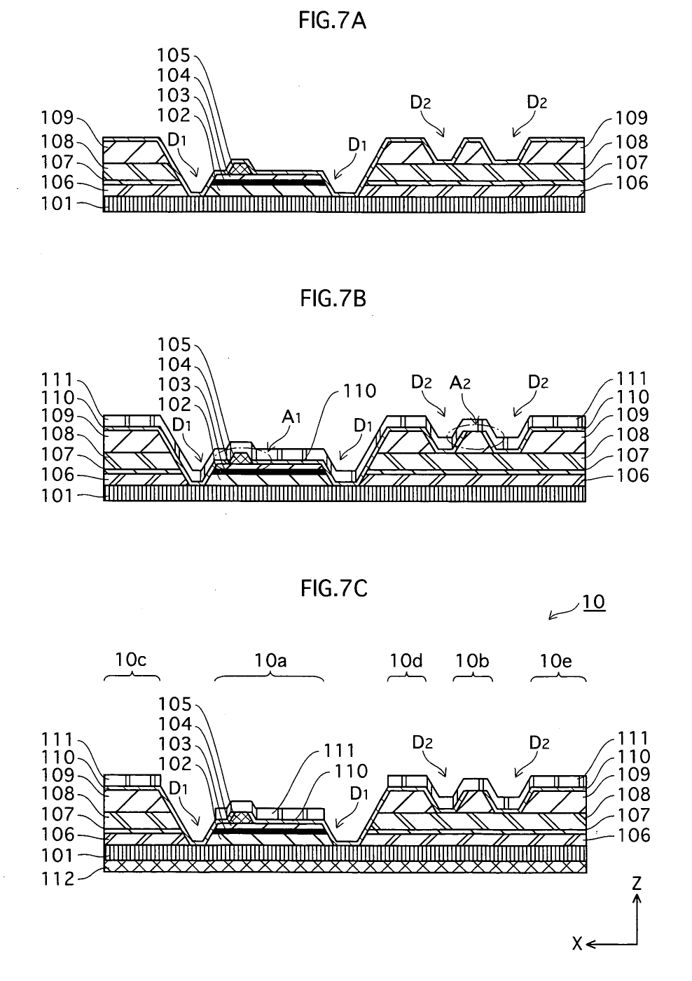

Next, the dielectric film 110 made of, for example, SiO₂ is deposited over the entire surface by the CVD technique as shown in FIG. 7A.

As shown in FIG. 7B, the dielectric film 110 on the p-type second cladding layer 105 in the area where the IR laser diode portion 10a is to be formed as well as on the p-type second cladding layer 109 in the area where the red laser diode portion 10b is to be formed is selectively removed to thereby form a structure for current injection to the ridges. Then, the p-type electrode 111 is deposited over the entire surface by vapor deposition.

The p-type electrode 111 is removed, by photolithography and etching, from the inclined planes and basal planes of the grooves D₁ adjoining where the IR laser diode portion 10a is to be formed, as shown in FIG. 7C. Then, the dual-wavelength semiconductor laser 10 is complete by uniformly forming the n-type electrode 112 over the lower main surface of the substrate 101 in the z-direction by vapor deposition. Namely, the area between the grooves D₁ is the IR laser diode portion 10a, while the area between the grooves D₂ is the red laser diode portion 11b. In addition, projecting portions other than the IR laser diode portion 10a and red laser diode portion 10b are the neighboring members 10c-10e.

Note that Table 1 shows examples of a constituent material, a conductive type, thickness, and carrier concentration of each component.

[First Modification]

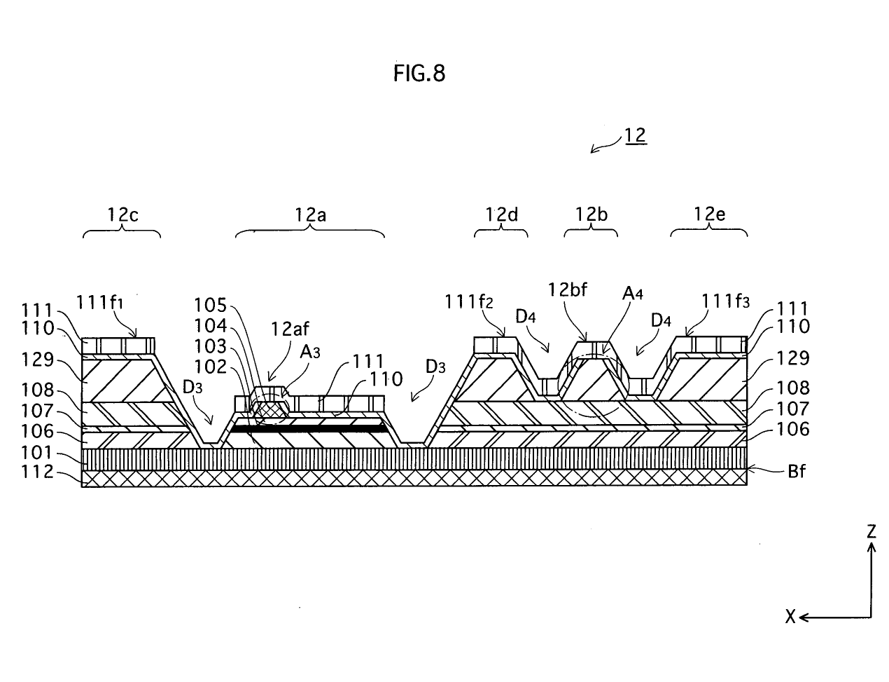

Next is described a configuration of a dual-wavelength semiconductor laser 12 according to a first modification with the aid of FIG. 8.

As shown in FIG. 8, the dual-wavelength semiconductor laser 12 of the first modification has the same basic components as the dual-wavelength semiconductor laser 10 of the first embodiment above. In FIG. 8, the same numerical symbols are used for the same components as in the first embodiment, and different numerical symbols are given only to components different from in the first embodiment. The following provides an account focusing on a difference of the first modification from the first embodiment. Note that the present modification is again a mere example, and the present invention is not limited to this. Therefore, the components other than the characterizing parts of the present invention can be changed accordingly.

As shown in FIG. 8, the dual-wavelength semiconductor laser 12 is characterized by that the thickness of the red laser's p-type second cladding layer 129 changes from region to region, which is the difference from the dual-wavelength semiconductor laser 10 of the first embodiment. In the present modification, the p-type second cladding layer 129 in the neighboring members is made thicker than in the red laser diode portion 12b.

The dual-wavelength semiconductor laser 12 of the present modification having the above configuration is capable of preventing the substrate 101 from being tilted in the junction-down mounting process, as with the dual-wavelength semiconductor laser 10 of the first embodiment above. Furthermore, the laser 12 of the present modification is able to further effectively reduce stress concentrating on the ridges A₃ and A₄ during the junction-down mounting process, as compared with the laser 10. That is, by making the p-type second cladding layer 129 in the neighboring members 12c-12e thicker, the difference between the top surface position of the neighboring members 12c-12e (i.e. the reference points 111f₁-111f₃) and that of each of the diode portions 12a and 12b (the reference points 12af and 12bf) in the z-direction with respective to the reference point Bf can be made large. Consequently, the diode portions 12a and 12b are less likely to be damaged during the junction-down mounting process.

[Second Modification]

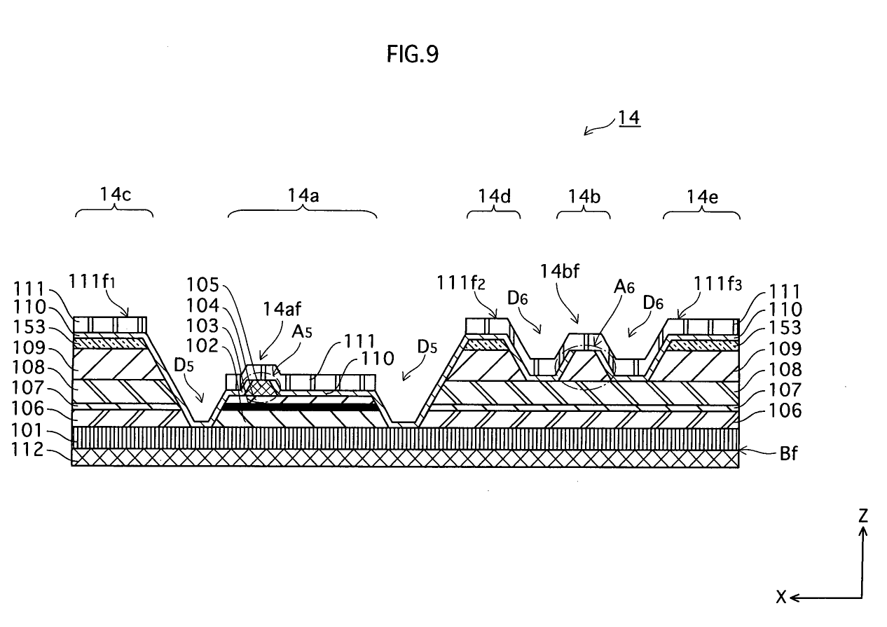

Next is described a configuration of a dual-wavelength semiconductor laser 14 according to a second modification with the aid of FIG. 9. Note that the following provides an account of the present modification, focusing on a difference from the dual-wavelength semiconductor lasers 10 and 12 of the first embodiment and the first modification, respectively.

As shown in FIG. 9, the dual-wavelength semiconductor laser 14 of the present modification has a configuration in which a second protective layer 153 is inserted between the p-type second cladding layer 109 and the dielectric film 110 in the neighboring members 14c-14e. Other components are the same with those in the dual-wavelength semiconductor laser 10 of the first embodiment. Here, the second protective layer 153 included as a component of the dual-wavelength semiconductor laser 14 can be made of the same material used for the red laser's p-type second cladding layer 109, i.e. (Al_{0.7}Ga_{0.3})_{0.5}In_{0.5}P (Zn dope), for example.

In the dual-wavelength semiconductor laser 12 of the first modification, the thickness of the p-type second cladding layers 129 in the neighboring members 12c-12e is modified so that their top surface positions (i.e. the reference points 111f₁-111f₃) are set higher than the top surface positions of the diode portions 12a and 12b (the reference points 12af and 12bf), respectively, in the z-direction. Herewith, it is possible to reduce the stress concentrating on the ridges A₃ and A₄ during the junction-down mounting process.

On the other hand, in the dual-wavelength semiconductor laser 14 of the present modification, the second protective layer 153 is inserted in neighboring members 14c-14e so that the difference between the top surface position of the neighboring members 12c-12e (the reference points 111f₁-111f₃) and that of each of diode portions 14a and 14b (reference points 14af and 14bf) in the z-direction with respect to the reference point Bf becomes large. Accordingly, the dual-wavelength semiconductor laser 14 of the present modification is also capable of protecting ridges A₅ and A₆ in the junction-down mounting process as well as preventing the substrate 101 from being tilted, as with the above first embodiment and first modification. Note that, compared to the first modification, the present modification allows to set the top surface positions of the neighboring members 12c-12e (the reference points 111f₁-111f₃) with higher dimensional accuracy.

Here, assume that, in the z-direction, the heights of the neighboring members 14c-14e each measured from the reference point Bf in the substrate 101 to the upper main surface of the p-type second cladding layer 109 are shorter than the height of the red laser diode portion 14b measured from the reference point Bf to the upper main surface of the p-type second cladding layer 109. Even in such a case, by adjusting the thicknesses of the dielectric film 110 and p-type electrode 111, the heights of the neighboring members 14c-14e (i.e. from the reference point Bf to the upper surface of the p-type electrode 111) in which the second protective layer 153 is inserted can be set equal to or higher than the top surface positions (the reference points 14af and 14bf) of the diode portions 14a and 14b in relation to the reference point Bf of the substrate 101. In this case also, it is possible to achieve effects of preventing the tilt of the substrate 101 and reducing the stress concentration on the ridges A₅ and A₆ in the junction-down mounting process.

2. Second Embodiment

The following describes a dual-wavelength semiconductor laser 20 according to a second embodiment with the aid of drawings. The dual-wavelength semiconductor laser 20 also adopts the double-channel ridge waveguide structure, and has a configuration in which an IR laser diode portion having an oscillation wavelength of 780 nm and a red laser diode portion having an oscillation wavelength of 660 nm are formed together on a shared substrate.

2.1 Configuration of Laser

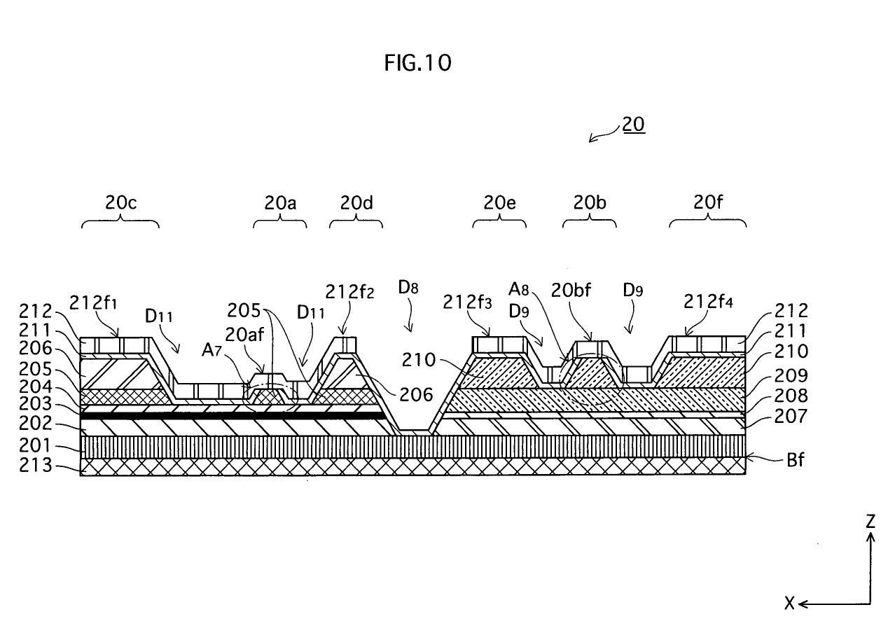

First, the configuration of the dual-wavelength semiconductor laser 20 of the present embodiment is described with the aid of FIG. 10. The reflecting mirrors arranged in such a way as to face the cleavage plane of crystal are left out from the figure, as in the case of FIG. 4.

As shown in FIG. 10, the dual-wavelength semiconductor laser 20 of the present embodiment has a configuration in which an IR laser diode portion 20a and a red laser diode portion 20b are formed, on an n-type GaAs substrate 201 to be a shared base, to the left and right of an isolation groove D₈, respectively, in the x-direction. In the x-direction in FIG. 10, neighboring members 20c and 20d are formed in the vicinity of the IR laser diode portion 20a, and neighboring members 20e and 20f are formed in the vicinity of the red laser diode portion 20b.

The IR laser diode portion 20a is, as shown in FIG. 10, composed of an IR laser's n-type cladding layer 202, an IR laser's active layer 203, an IR laser's p-type first cladding layer 204, an IR laser's p-type second cladding layer 205, a dielectric film 211, a p-type electrode 212 which are formed in layers on one of the main surfaces of the substrate 201 (the upper main surface in the z-direction in FIG. 10), as well as an n-type electrode 213 formed on the other main surface of the substrate 201 (the lower main surface in the z-direction in FIG. 10). Here, the entire upper main surface of the p-type first cladding layer 204 is covered by the dielectric film 211, except for where the p-type second cladding layer 205 is superimposed. On the other hand, the main surface of the p-type second cladding layer 205 superimposed over the top of the p-type first cladding layer 204 is not blanketed by the dielectric film 211 and therefore has direct contact with the p-type electrode 212, and a ridge A₇ is formed. The configuration here is the same in the above first embodiment.

Note that the active layer 203 in the IR laser diode portion 20a is formed by a quantum well structure with an oscillation wavelength band of 780 nm.

The neighboring members 20c and 20d are formed on both sides of the IR laser diode portion 20a, with grooves D₁₁ separating the neighboring members 20c and 20d from the IR laser diode portion 20a. As with the IR laser diode portion 20a, the neighboring members 20c and 20d each have a configuration in which the n-type cladding layer 202, active layer 203, p-type first cladding layer 204, p-type second cladding layer 205, dielectric film 211, and p-type electrode 212 are formed in layers on the main surface of the substrate 201. The difference of the neighboring members 20c and 20d from the IR laser diode portion 20a is, however, that an IR laser's second protective layer 206 is inserted between the p-type second cladding layer 205 and dielectric film 211. Additionally, in the neighboring members 20c and 20d, the dielectric film 211 is inserted with no break between the p-type electrode 212 and the p-type second cladding layer 205 or between the p-type electrode 212 and the second protective layer 206. Here, the p-type second cladding layer 205 in the neighboring members 20c and 20d also has an additional function as an IR laser's protective layer.

On the other hand, the red laser diode portion 20b is, as shown in FIG. 10, composed of a red laser's n-type cladding layer 207, a red laser's active layer 208, a red laser's p-type first cladding layer 209, a red laser's p-type second cladding layer 210, the dielectric film 211, the p-type electrode 212 which are formed in layers on that main surface of the substrate 201 which the IR laser diode portion 20a is formed (the upper main surface in the z-direction in FIG. 10), as well as the n-type electrode 213 shared with the IR laser diode portion 20a formed on the other main surface of the substrate 201 (the lower main surface in the z-direction in FIG. 10). Here, in the red laser diode portion 20b also, the dielectric film 211 on the upper surface of the p-type second cladding layer 210 has been removed so that the p-type second cladding layer 210 has direct contact with the p-type electrode 212, and a ridge A₈ is formed.

The neighboring members 20e and 20f are formed on both sides of the red laser diode portion 20b, with grooves D₉ separating the neighboring members 20e and 20f from the red laser diode portion 20b. The neighboring members 20e and 20f each have a configuration in which the n-type cladding layer 207, active layer 208, p-type first cladding layer 209, p-type second cladding layer 210, dielectric film 211, p-type electrode 212 are formed in layers on the main surface of the substrate 201. In the neighboring members 20e and 20f also, as in the neighboring members 20c and 20d above, the dielectric film 211 is inserted with no break between the p-type second cladding layer 210 and the p-type electrode 212. Here, the p-type second cladding layer 210 in the neighboring members 20e and 20f also has an additional function as a red laser's protective layer.

Regarding the grooves D₈, as in the dual-wavelength semiconductor laser 10 of the first embodiment, the layers 202-206/207-211 are removed so that the dielectric film 211 has direct contact with the substrate 201. In addition, the p-type electrode 212 is also removed.

2.2 Height Relationship of Respective Portions and Regions

As to the dual-wavelength semiconductor laser 20 of the present embodiment also, the height relationship of the respective diode portions 20a and 20b and the neighboring members 20c-20f is described.

As shown in FIG. 10, in the dual-wavelength semiconductor laser 20 of the present embodiment also, the IR laser diode portion 20a is set to be the lowest among the two diode portions 20a and 20b and four neighboring members 20c-20f. The red laser diode portion 20b is set to be the second lowest of them, while the neighboring members 20c-20f all having the same height are set to be higher than both the diode portions 20a and 20b. Here, the height difference between the red laser diode portion 20b and the neighboring members 20c-20f is only the thickness of the dielectric film 211, as in the first embodiment, and therefore it can be considered that they all have substantially the same height.

To be more specific, here the position of the lower main surface of the substrate 201 (the main surface on which the n-type electrode 213 is laid) in the z-direction is used as a reference position Bf. The positions, in the z-direction, of the individual upper surfaces of the p-type electrode 212 in the diode portions 20a and 20b and the neighboring members 20c-20f are also used as reference points 20af, 20bf, 212f₁, 212f₂, 212f₃, and 212f₄, respectively. In this situation, the heights of these portions are designed to satisfy the following positional relationships in the z-direction.
(20af-Bf)<(20bf-Bf) Equation 4.
(20bf-Bf)<(212f₁-Bf)=(212f₄-Bf) Equation 5.
(212f₁-Bf)=(212f₂-Bf)=(212f₃-Bf)=(212f₄-Bf) Equation 6.

Note that, as in the first embodiment above, Equation 5 can be deemed as:
(20bf-Bf)≈(212f₁-Bf)=(212f₄-Bf) Equation 7.
2.3 Advantageous Effects of Dual-Wavelength Semiconductor Laser 20

In the dual-wavelength semiconductor laser 20 according to the second embodiment, the neighboring members 20c-20f are set higher than the IR laser diode portion 20a while being set slightly higher than the red laser diode portion 20b. The neighboring members 20c and 20f are disposed outward of the two diode portions 20a and 20b in the x-direction while the neighboring members 20d and 20e are positioned between the diode portions 20a and 20b.

In the dual-wavelength semiconductor laser 20 having such a height relationship, since the substrate 201 does not tilt against the submount during the junction-down mounting process, stress does not concentrate on the diode portion having a thicker double-heterojunction structure (the red laser diode portion 20b in FIG. 10), and thereby the characteristics of the semiconductor laser can be maintained at an effective level, as with the dual-wavelength semiconductor laser 10 above. Here, the dual-wavelength semiconductor laser 20 of the present embodiment has, between the diode portions 20a and 20b, the two neighboring members 20d and 20e standing higher than these diode portions 20a and 20b. Therefore, the dual-wavelength semiconductor laser 20 is capable of reducing the concentration of stress on the ridges A₇ and A₈ in a more reliable fashion, as compared with the dual-wavelength semiconductor laser 10 in which only one neighboring member 10d is disposed between the diode portions.

In addition, the dual-wavelength semiconductor laser 20 of the present embodiment is less likely to be subject to constraints on heights of the diode portions 20a and 20b in the laser designing, and has an advantageous effect in terms of degrees of freedom in designing, as with the dual-wavelength semiconductor laser 10 described above.

Table 2 shows examples of individual components used for the dual-wavelength semiconductor laser 20.

TABLE 2

| | | Conductive | Thickness | Carrier |
|---|---|---|---|---|
| Component | Material | Type | (μm) | Concentration (cm⁻³) |
| Substrate 201 | GaAs | n type | — | 1 × 10¹⁸ |
| | (Si dope) | | | |
| IR laser n-type | (Al_{0.7}Ga_{0.3})_{0.5}In_{0.5}P | n-type | 2.0 | 1 × 10¹⁸ |
| cladding layer | (Si dope) | | | |
| 202 | | | | |
| IR laser active | GaAs/Al_{0.4}Ga_{0.6}As | — | 0.08 | — |
| layer 203 | Quantum Well | | | |
| IR laser p-type | (Al_{0.7}Ga_{0.3})_{0.5}In_{0.5}P | p type | 0.2 | 5 × 10¹⁷ |
| first cladding | (Zn dope) | | | |
| layer 204 | | | | |
| IR laser p-type | (Al_{0.7}Ga_{0.3})_{0.5}In_{0.5}P | p type | 1.4 | 1 × 10¹⁸ |
| second cladding | (Zn dope) | | | |
| layer 205 | | | | |
| Red laser second | Al_{0.5}In_{0.5}P | p type | 1.07 | 5 × 10¹⁷ |
| protective layer | (Zn dope) | | | |
| 206 | | | | |
| Red laser n-type | (Al_{0.7}Ga_{0.3})_{0.5}In_{0.5}P | n type | 2.0 | 1 × 10¹⁸ |
| cladding layer | (Si dope) | | | |
| 207 | | | | |
| Red laser active | Ga_{0.45}In_{0.55}/ | — | 0.15 | — |
| layer 208 | (Al_{0.5}Ga_{0.5})_{0.5}In_{0.5}P | | | |
| | Quantum Well | | | |
| Red laser p-type | (Al_{0.7}Ga_{0.3})_{0.5}In_{0.5}P | p type | 0.4 | 3 × 10¹⁷ |
| first cladding | (Zn dope) | | | |
| layer 209 | | | | |
| Red laser p-type | (Al_{0.7}Ga_{0.3})_{0.5}In_{0.5}P | p type | 2.2 | 8 × 10¹⁷ |
| second cladding | (Zn dope) | | | |
| layer 210 | | | | |

When the components shown in Table 2 are adopted, the height of the IR laser diode portion 20a (20af-Bf) is 3.68 μm, and the height of the red laser diode portion 20b (20bf-Bf) is 4.75 μm. Thus, even if there is a height difference between the diode portions 20a and 20b, the laser 20 is supported by the top surfaces of the neighboring members 20c-20f in the junction-down mounting process. Thereby, in the dual-wavelength semiconductor laser 20 of the present embodiment also, the tilt of the substrate 201 in the junction-down mounting process is prevented, which in turn prevents the concentration of stress on the ridges A₇ and A₈.

2.4 Manufacturing Method of Dual-Wavelength Semiconductor Laser 20

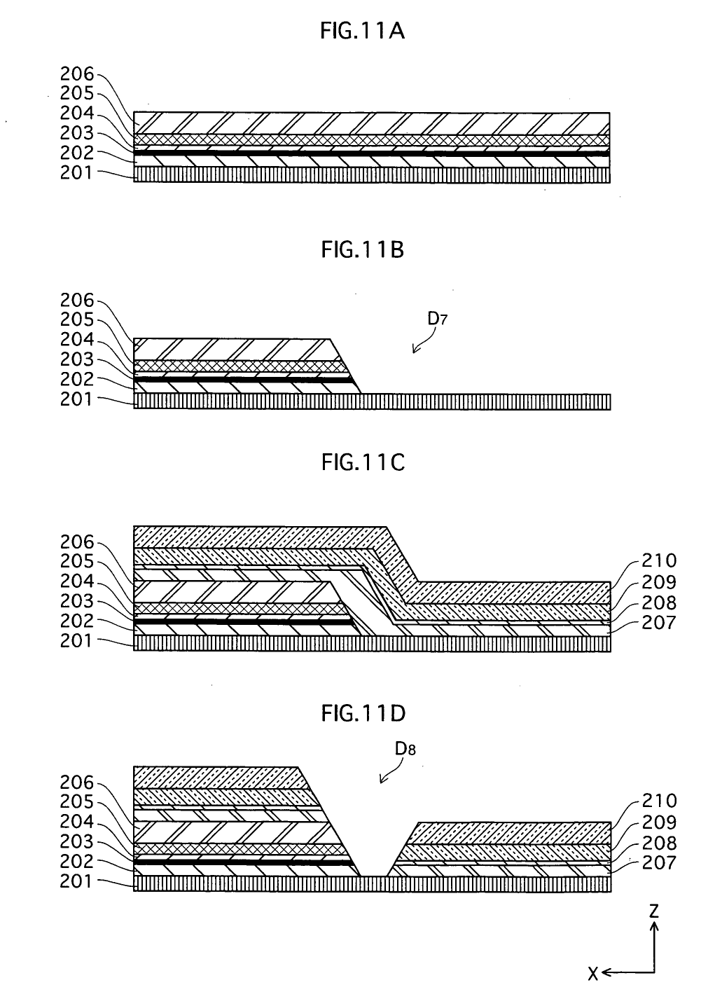

Next is described a method for manufacturing the dual-wavelength semiconductor laser 20 of the second embodiment with the aid of FIGS. 11A to 13C. FIGS. 11A to 13C are process drawings showing main steps of the manufacturing procedure of the dual-wavelength semiconductor laser 20 according to the present embodiment. As in the first embodiment, detailed descriptions of publicly known technologies regarding MOCVD crystal growth, photolithography, etching of the semiconductor, dielectric film, and electrodes, CVD dielectric film deposition, and vapor deposition for electrode formation are left out from the present embodiment.

By using the MOCVD technique, the IR laser's n-type cladding layer 202, the IR laser's active layer 203, the IR laser's p-type first cladding layer 204, the p-type second cladding layer 205, and the IR laser's second protective layer 206 are formed on the n-type GaAs substrate 201 in the stated order, as shown in FIG. 11A. The IR laser's active layer 203 is formed by a quantum well structure with an oscillation wavelength band of 780 nm.

Next, the n-type cladding layer 202, active layer 203, p-type first cladding layer 204, p-type second cladding layer 205, and second protective layer 206 are removed by photolithography and etching to thereby form a depression D₇ having the substrate 201 as its basal plane, as shown in FIG. 11B.

As shown in FIG. 11C, by the MOCVD technique, the red laser's n-type cladding layer 207, red laser's active layer 208, red laser's p-type first cladding layer 209, and red laser's p-type second cladding layer 210 are formed over the entire surface including the depression D₇ in the stated order. The red laser's active layer 208 is formed by a quantum well structure with an oscillation wavelength band of 660 nm.

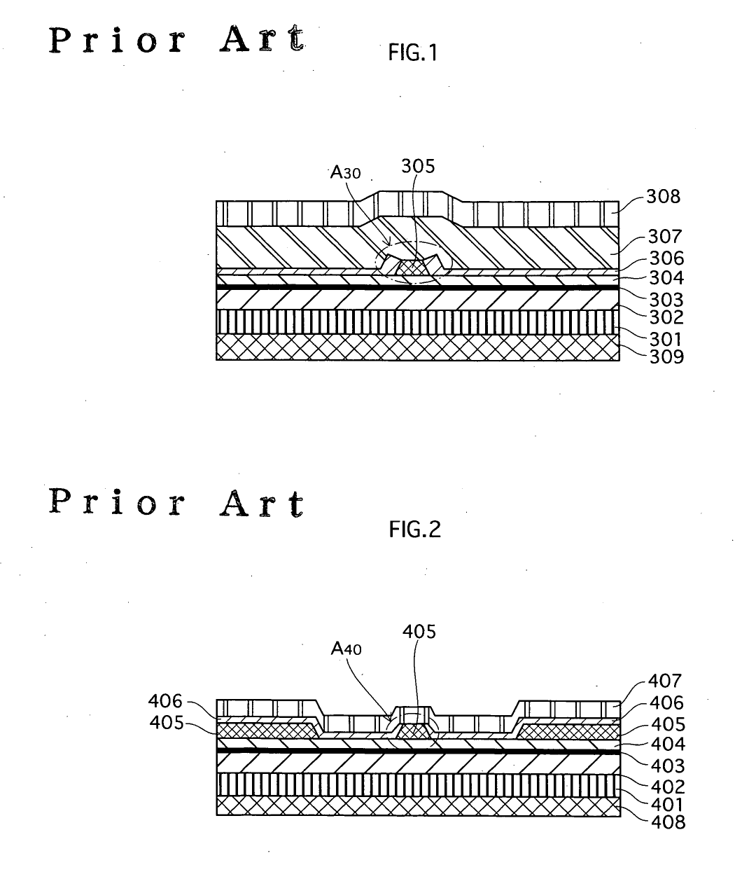

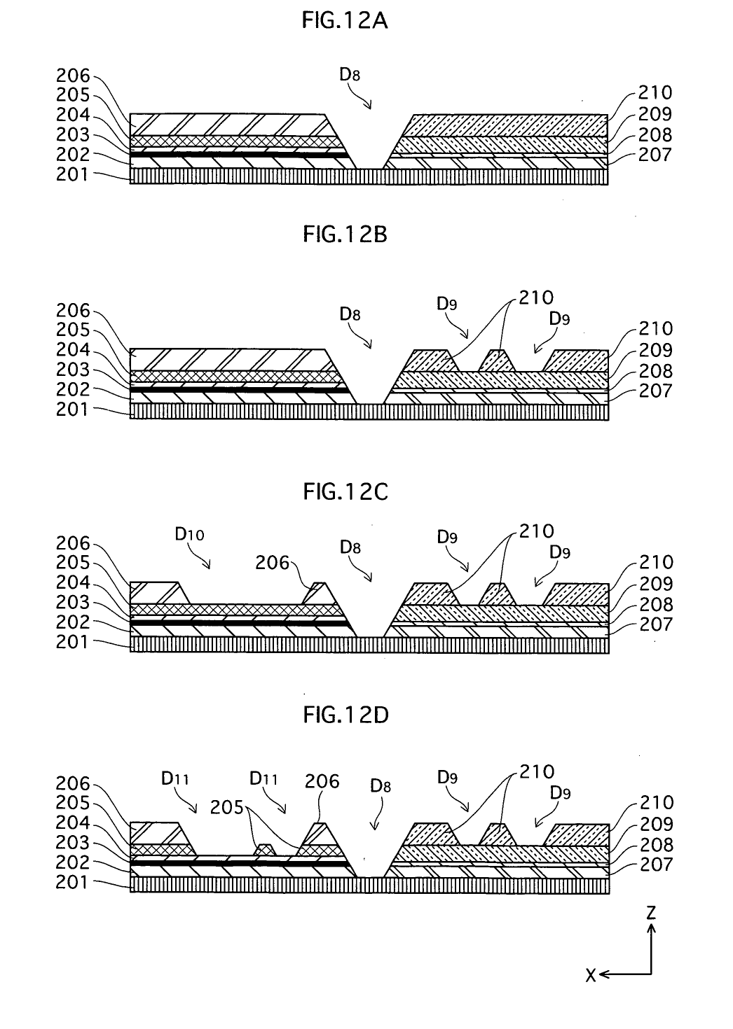

Next, as shown in FIG. 1D, the n-type cladding layer 207, active layer 208, p-type first cladding layer 209, and p-type second cladding layer 210 are removed from a section forming the boundary between a portion where the IR laser diode portion 20a is to be formed and a portion where the red laser diode portion 20b is to be formed, by photolithography and etching to thereby form the isolation groove D₈. Then, the n-type cladding layer 207, active layer 208, p-type first cladding layer 209, and p-type second cladding layer 210 remaining in the area where the IR laser diode portion 20a is to be formed are removed by photolithography and etching, as shown in FIG. 12A.

As shown in FIG. 12B, part of the p-type second cladding layer 210 is removed from where the red laser diode portion 20b is to be formed as well as from the vicinity thereof by photolithography and etching to thereby form the grooves D₉. Herewith, a ridge is formed with the remaining p-type second cladding layer 210 sandwiched between the two grooves Dg. Note that the p-type second cladding layer 210 remaining on the outward sides of the two grooves D₉ functions as a red laser's protective layer when the laser 20 is complete.

As shown in FIG. 12C, by photolithography and etching, part of the second protective layer 206 is removed from where the IR laser diode portion 20a is to be formed as well as from the vicinity to thereby form a depression D₁₀.

As shown in FIG. 12D, the grooves D₁₁ are formed in the area where the groove D₁₀ has been formed, by removing part of the p-type second cladding layer 205 by photolithography and etching. A ridge is formed with the remaining p-type second cladding layer 205 sandwiched between the two grooves D₁₁. Additionally, the p-type second cladding layer 205 remaining on the outward sides of the two grooves D₁₁ functions as a first protective layer of the IR laser diode portion 20a when the laser 20 is complete. Namely, on both outer sides of the grooves D₁₁, the first protective layer (the p-type second cladding layer 205) and the second protective layer 206 remain formed in layers.

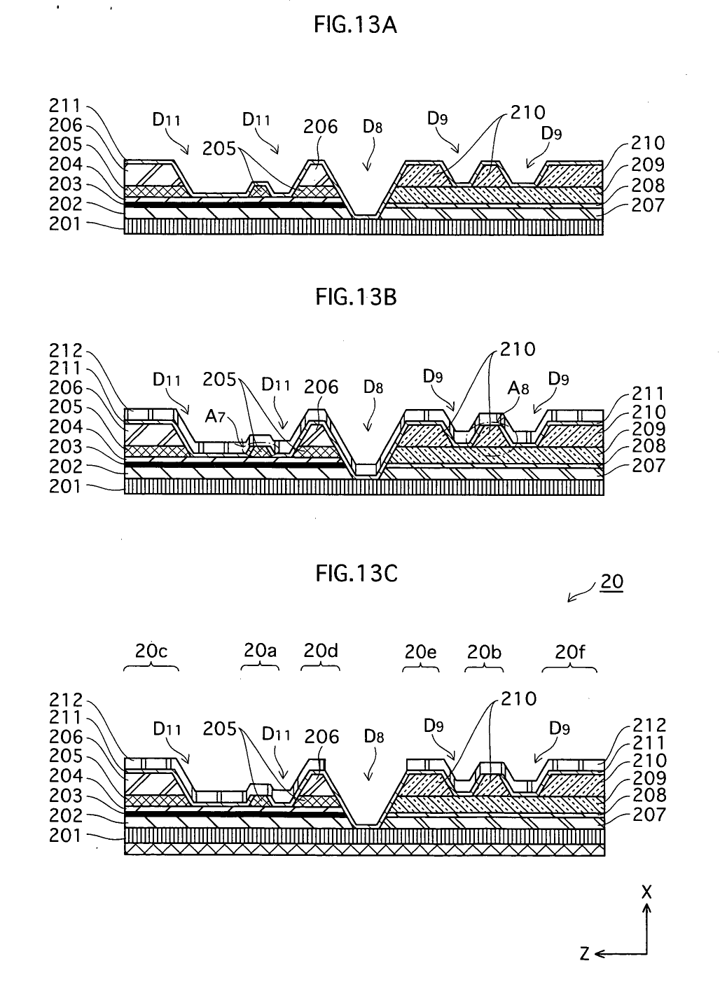

Next, the dielectric film 211 made of, for example, SiO₂ is deposited over the entire surface by the CVD technique, as shown in FIG. 13A.

As shown in FIG. 13B, the dielectric film 211 over the p-type second cladding layer 205 in the area where the IR laser diode portion 20a is to be formed as well as over the p-type second cladding layer 210 in the area where the red laser diode portion 20b is to be formed are selectively removed by photolithography and etching to form a structure for current injection to the ridges. Then, the p-type electrode 212 is deposited over the entire surface by vapor deposition.

Lastly, as shown in FIG. 13C, the p-type electrode 212 is removed by photolithography and etching from the inclined planes and basal plane of the groove D₈, and thereby the IR laser diode portion 20a and the red laser diode portion 20b are isolated from each other. Subsequently, the n-type electrode 213 is deposited over the entire other main surface of the substrate 201 by vapor deposition to complete the dual-wavelength semiconductor laser 20.

Note that Table 2 shows examples of a constituent material, a conductive type, thickness, and carrier concentration of each component.

[Third Modification]

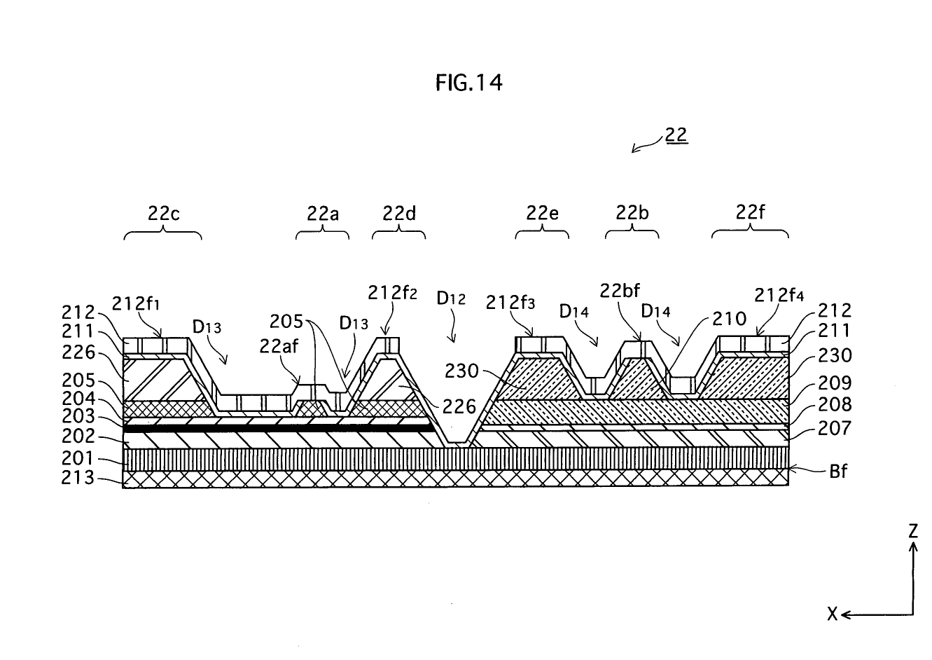

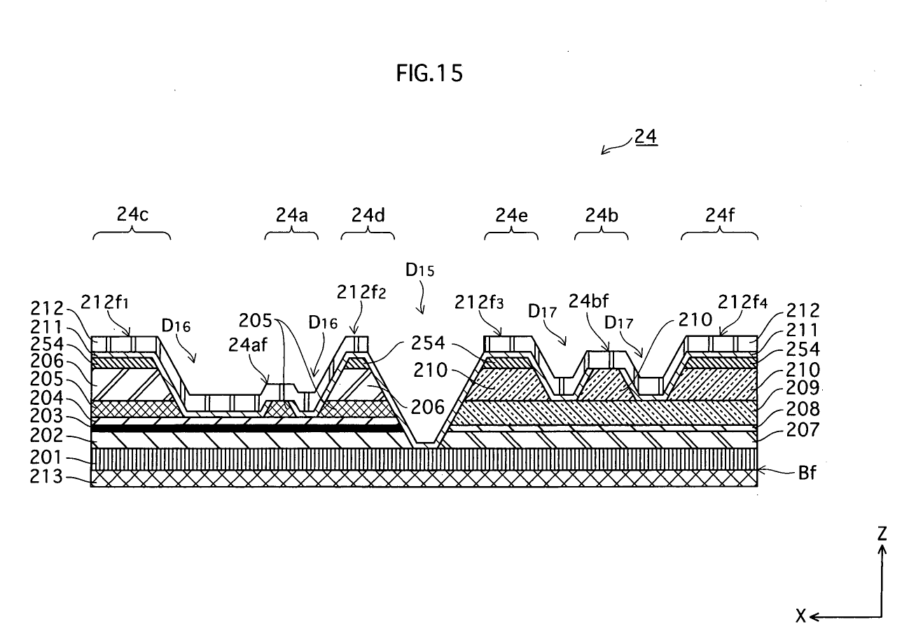

Next is described a configuration of a dual-wavelength semiconductor laser 22 according to a third modification with the aid of FIG. 14.

As shown in FIG. 14, the dual-wavelength semiconductor laser 22 of the third modification differs from the dual-wavelength semiconductor laser 20 of the second embodiment above in thicknesses of an IR laser's p-type second cladding layer 226 and a red laser's p-type second cladding layer 230, while having the same basic components as the dual-wavelength semiconductor laser 20.

As shown in FIG. 14, in the dual-wavelength semiconductor laser 22 of the present modification, the p-type second cladding layer 226 in the neighboring members 22c and 22d is made thicker than the second protective layer 206 in FIG. 10. In addition, the p-type second cladding layer 230 in the neighboring members 22e and 22f is set to have a different thickness from the p-type second cladding layer 210 in the red laser diode portion 22b. Thicknesses of the p-type second cladding layer 226 in the neighboring members 22c and 22d and the p-type second cladding layer 230 in the neighboring members 22e and 22f are set so that the top surfaces of all the neighboring members 22c-22f (i.e. the reference points 212f₁-212f₄) are placed at the same point in the z-direction with respect to the reference point Bf. By setting the p-type second cladding layers 226 and 230 in this way, the dual-wavelength semiconductor laser 22 of the present modification is capable of setting the top surface positions of the neighboring members 22c-22f (i.e. the reference points 212f₁-212f₄) higher than the top surface positions of the diode portions 22a and 22b (the reference point 22af and 22bf) in a reliable fashion.

The dual-wavelength semiconductor laser 22 of the present modification having the above configuration is capable of preventing the substrate 201 from being tilted in the junction-down mounting process, as with the dual-wavelength semiconductor laser 20 of the second embodiment. Furthermore, the dual-wavelength semiconductor laser 22 is able to further effectively reduce the stress concentrating on the ridges during the junction-down mounting process, as compared with the laser 20. That is, by making the p-type second cladding layer 226/230 in the neighboring members 22c and 22d/22e and 22f thicker than the p-type second cladding layer 205/210 in the diode portion 22a/22b, the difference between the top surface position of the neighboring members 22c-22f (i.e. the reference points 212f₁-212f₄) and that of each of the diode portions 22a and 22b (reference points 22af and 22bf) in the z-direction with respect to the reference point Bf can be made large. Consequently, the diode portions 22a and 22b are less likely to be damaged in the junction-down mounting process.

[Fourth Modification]

Next is described a configuration of a dual-wavelength semiconductor laser 24 according to a fourth modification with the aid of FIG. 15.

As shown in FIG. 15, the dual-wavelength semiconductor laser 24 of the present modification has a structure in which a third protective layer 254 is inserted between the dielectric film 211 and the second protective layer 206 in the neighboring members 24c and 24d while inserted between the dielectric film 211 and the p-type second cladding layer 210 in the neighboring members 24e and 24f. Other components are the same with those in the dual-wavelength semiconductor laser 20 of the second embodiment. Here, the third protective layer 254 included as a component of the dual-wavelength semiconductor laser 24 can be made of the same material used for the second protective layer 153 of the laser 14 according to the second modification, i.e. (Al_{0.7}Ga_{0.3})_{0.5}In_{0.5}P (Zn dope), for example.

In the dual-wavelength semiconductor laser 24 of the present modification, the third protective layer 254 is inserted in neighboring members 24c-24f so that the difference between the top surface position of the neighboring members 24c-24f (i.e. the reference points 212f₁-212f₄) and that of each of diode portions 24a and 24b (reference points 24af and 24bf) in the z-direction with respect to the reference point Bf becomes large. Accordingly, the dual-wavelength semiconductor laser 24 is also capable of protecting ridges during the junction-down mounting process as well as preventing the substrate 201 from being tilted, as with the above second embodiment and the third modification. Note that, compared to the third modification above, the present modification allows to set the top surface positions (212f₁-212f₄) of the neighboring members 24c-24f with higher dimensional accuracy.

Here, assume that, in the z-direction, the heights of the neighboring members 24c and 24d each measured from the reference point Bf of the substrate 201 to the upper main surface of the second protective layer 206 as well as the heights of the neighboring members 24e and 24f each measured from the reference point Bf to the upper main surface of the p-type second cladding layer 210 are shorter than the height of the red laser diode portion 24b measured from the reference point Bf to the upper main surface of the p-type second cladding layer 210. Even in such a case, by adjusting the thicknesses of the dielectric film 211 and the p-type electrode 212, the heights of the neighboring members 24c-24f (i.e. from the reference point Bf to the upper surface of the p-type electrode 212) in which the third protective layer 254 is inserted can be set equal to or higher than the top surface positions (the reference points 24af and 24bf) of the diode portions 24a and 24b in relation to the reference point Bf of the substrate 201. In this case also, it is possible to achieve effects of preventing the tilt of the substrate 201 and reducing the stress concentration on the ridges in the junction-down mounting process.

3. Additional Particulars

Although the first and second embodiments and the first to fourth modifications take as examples the dual-wavelength semiconductor lasers each having an infrared laser diode portion and a red laser diode portion formed together on a shared substrate, the present invention is not limited to these. For example, three or more laser diode portions each emitting light at a different wavelength may be formed together on a single substrate. In addition, the oscillation wavelengths of laser diode portions to be formed are also not limited to the above. By adopting the configurations of the semiconductor lasers according to the present invention, the tilt of the substrate against the submount in the junction-down mounting process is effectively prevented, and stress does not concentrate on the ridges of the diode portions. Accordingly, even when multiple laser diode portions each having a different oscillation wavelength are to be formed together on a shared substrate, degrees of freedom in designing the laser diode portions can be maintained at a high level.

In the first and second embodiments above, Tables 1 and 2 show specific materials and thickness of layers by way of example. However, these are provided in order to make the relationship of the top surface positions of the respective portions (i.e. the laser diode portions and their neighboring members) in the lasers 10 and 20 clearly understandable. Thus, it is evident that the present invention is not confined to those materials and values shown in the tables.

The first and second embodiments and the first to fourth modifications each have a configuration in which the infrared laser diode portion 10a/12a/14a/20a/22a/24a emitting infrared light in the 780-nm band wavelength and the red laser diode portion 10b/12b/14b/20b/22b/24b emitting red light in the 660-nm band wavelength. However, the wavelengths of the emitting light are not limited to these. Note however that it is desirable for practical configurations of the lasers that one diode portion have an emitting wavelength between 750 nm and 820 nm while the other diode portion have an emitting wavelength between 630 nm and 690 nm.

In each of the lasers 10/12/14/20/22/24 of the first and second embodiments and the first to fourth modifications, respectively, the neighboring member or members 10c/12c/14c/20d and 20e/22d and 22e/24d and 24e are provided between the infrared laser diode portion 10a/12a/14a/20a/22a/24a and the red laser diode portion 10b/12b/14b/20b/22b/24b. However, these are not indispensable. Namely, when there are two or more laser diode portions formed together on a shared substrate, the advantageous effects described above can be achieved by: forming at least two neighboring members on the outer edge of the substrate surrounding the entire area in which these laser diode portions are formed; setting the top surface positions of these neighboring members higher than the top surface positions of the individual laser diode portions; and setting the top surface positions of these neighboring members to the same height.

Although the present invention has been fully described by way of examples with reference to the accompanying drawings, it is to be noted that various changes and modifications will be apparent to those skilled in the art. Therefore, unless otherwise such changes and modifications depart from the scope of the present invention, they should be constructed as being included therein.

What is claimed is:

1. A semiconductor laser comprising:
a first laser diode portion positioned on top of a main surface of a substrate, emitting light of a first wavelength, and having a layered structure which includes a first-conductive-type cladding layer, an active layer, and a ridge-stripe second-conductive-type cladding layer successively stacked on the substrate main surface in a stated order; and
a second laser diode portion positioned apart from the first laser diode portion on the substrate main surface, emitting light of a second wavelength, and having a layered structure which includes a first-conductive-type cladding layer, an active layer, and a ridge-stripe second-conductive-type cladding layer successively stacked on the substrate main surface in a stated order, wherein
the first and second laser diode portions are disposed so as to have top surfaces of the layered structures thereof positioned at different heights, in a thickness direction of the substrate, with respect to an opposite main surface of the substrate,
first and second members each having a layered structure are respectively formed on an outer edge of the substrate, and
the first and second members are disposed (i) in a direction along the substrate main surface so as to sandwich therebetween where the first and second laser diode portions are formed, and (ii) in the thickness direction so as to have top surfaces of the corresponding layered structures both positioned at a same height which is higher than or equal to a higher of the first and second laser diode portions.

2. The semiconductor laser of claim 1, wherein
a third member having a layered structure is formed, on the substrate main surface, between the first and second laser diode portions, and
the third member is disposed so as to have a top surface of the corresponding layered structure positioned at the same height as the first and second members in the thickness direction.

3. The semiconductor laser of claim 2, wherein
an isolation groove having a depth in the thickness direction is formed between the first and second laser diode portions,
the third member is formed between the isolation groove and the first laser diode portion,
a fourth member having a layered structure is formed, on the substrate, between the isolation groove and the second laser diode portion, and
the fourth member is disposed so as to have a top surface of the corresponding layered structure positioned at the same height as the first, second, and third members in the thickness direction.

4. The semiconductor laser of claim 3, wherein
each of the first, second, third, and fourth members has a semiconductor layer formed on the top surface of the corresponding layered structure with a layer surface thereof exposed.

5. The semiconductor laser of claim 4, wherein
each of the first and second laser diode portions has a semiconductor layer formed on the top surface of the corresponding layered structure with a layer surface thereof exposed, and
the semiconductor layers of the first and second laser diode portions and the semiconductor layers of the first, second, third, and fourth members are all made of same material.

6. The semiconductor laser of claim 1, wherein
each of the first and second laser diode portions has a dielectric film and a semiconductor electrode successively stacked on the corresponding second-conductive-type cladding layer in a stated order.

7. The semiconductor laser of claim 1, wherein
the first wavelength is in a range of 750 nm to 820 nm, inclusive, and the second wavelength is in a range of 630 nm to 690 nm, inclusive.

8. A semiconductor laser manufacturing method, comprising the steps of:
(a) forming a first laser diode portion on top of part of a main surface of a substrate by successively stacking a first-conductive-type cladding layer, an active layer, and a ridge-stripe second-conductive-type cladding layer on the substrate main surface in a stated order;
(b) forming a second laser diode portion on the substrate main surface, apart from the first laser diode portion, by successively stacking a first-conductive-type cladding layer, an active layer, and a ridge-stripe second-conductive-type cladding layer on the substrate main surface in a stated order; and
(c) forming first and second members each having a layered structure on an outer edge of the substrate main surface so as to sandwich therebetween where the first and second laser diode portions are formed, wherein
in the steps (a) and (b), the first and second laser diode portions are formed so as to have top surfaces of the stacked layers thereof positioned at different heights, in a thickness direction of the substrate, with respect to an opposite main surface of the substrate, and
in the step (c), the first and second members are formed so as to have top surfaces of the layered structures thereof both positioned at a same height which is higher than or equal to a higher of the first and second laser diode portions.

9. The semiconductor laser manufacturing method of claim 8, further comprising the step of:
(d) forming a third member having a layered structure, on the substrate main surface, between the first and second laser diode portions so as to have a top surface of the corresponding layered structure positioned at the same height as the first and second members in the thickness direction.

10. The semiconductor laser manufacturing method of claim 9, wherein
an isolation groove having a depth in the thickness direction is formed between the first and second laser diode portions,
the third member is formed between the isolation groove and the first laser diode portion, and
the semiconductor laser manufacturing method further comprising the step of:
(e) forming a fourth member having a layered structure, on the substrate main surface, between the isolation groove and the second laser diode portion so as to have a top surface of the corresponding layered structure positioned at the same height as the first, second, and third members in the thickness direction.

11. The semiconductor laser manufacturing method of claim 10, wherein
in the steps (c), (d), and (e), the first, second, third, and fourth members are formed so as to respectively have a semiconductor layer formed on the top surface of the corresponding layered structure with a layer surface thereof exposed.

12. The semiconductor laser manufacturing method of claim 11, wherein
in the steps (a) and (b), the first and second laser diode portions are formed so as to respectively have a semiconductor layer formed on top of the top surface of the corresponding stacked layers with a layer surface thereof exposed, and
in the steps (c), (d), and (e), the semiconductor layers of the first, second, third, and fourth members are made of same material as the semiconductor layers of the first and second laser diode portions.

13. The semiconductor laser manufacturing method of claim 8, wherein
in each of the steps (a) and (b), a dielectric film and a semiconductor electrode are successively stacked on the corresponding second-conductive-type cladding layer in a stated order.

14. The semiconductor laser device manufacturing method of claim 8, wherein
the steps (a) and (b) are implemented with the substeps of:
(o) successively stacking the first-conductive-type cladding layer, the active layer, and the second-conductive-type cladding layer on top of the substrate main surface in a stated order;
(p) selectively removing at least the second-conductive-type cladding layer and the active layer from part of the stacked layers formed in the substep (o);
(q) successively stacking a first-conductive-type cladding layer, an active layer, and a second-conductive-type cladding layer, in a stated order, on top of a top surface of the stacked layers after the substep (p) has finished in a manner to be superimposed over an entire extent of the substrate main surface;
(r) selectively removing one or more of the stacked layers formed in the substep (q) from both sides of where the first laser diode portion is to be formed;
(s) selectively removing at least two of the stacked layers formed in the substep (q) from where the first laser diode portion is to be formed;
(t) forming a first ridge stripe by selectively removing part of the second-conductive-type cladding layer of the substep (o) from where the first laser diode portion is to be formed; and
(u) forming a second ridge stripe by selectively removing part of the second-conductive-type cladding layer of the substep (q) from where the second laser diode portion is to be formed.
